(19) United States
(12) Patent Application Publication
(10) Pub. No.: US 2020/0013638 A1
(43) Pub. Date: Jan. 9, 2020

(54) SUBSTRATE PROCESSING APPARATUS

(71) Applicant: KCTECH CO., LTD., Anseong-si (KR)

(72) Inventor: Kang il CHO, Hwaseong-si (KR)

(73) Assignee: KCTECH CO., LTD., Anseong-si (KR)

(21) Appl. No.: 16/495,368

(22) PCT Filed: Feb. 5, 2018
(86) PCT No.: PCT/KR2018/001512

§ 371 Date: Sep. 18, 2019

(30) Foreign Application Priority Data
Jun. 14, 2017 (KR) 10-2017-0074719
Nov. 15, 2017 (KR) 10-2017-0152182

(51) Int. Cl. H01L 21/677; H01L 21/687; H01L 21/683

(52) U.S. Cl. CPC H01L 21/677; H01L 21/6838; H01L 21/68764

(57) ABSTRACT

The present invention relates to a substrate processing apparatus, wherein the substrate processing apparatus for coating chemical liquid on a substrate comprises: a substrate support for supporting a substrate, a chemical liquid coating unit for applying and coating the chemical liquid to the substrate, and a preliminary drying unit for preliminarily drying chemical liquid in a state supported by the substrate support whereby it is possible to obtain the effect of preventing the chemical liquid from flowing down and forming a chemical liquid coating film of uniform thickness.

### CROSS-REFERENCE TO RELATED APPLICATIONS

This U.S. non-provisional patent application claims priority under 35 U.S.C. § 119 of Korean Patent Application Nos. 10-2017-0074719 filed on Jun. 14, 2017 and 10-2017-0152182 filed on Nov. 15, 2017, the entire contents of which are hereby incorporated by reference.

### FIELD OF THE INVENTION

The present invention relates to a substrate processing apparatus, and more particularly, to a substrate processing apparatus capable of forming a liquid coating film having a uniform thickness.

### BACKGROUND OF THE INVENTION

Recently, various attempts have been made to increase the yield and productivity of semiconductors.

Among these, a panel level package (PLP) is a technology for packaging a high performance semiconductor chip having a large amount of input and output at a low cost without a printed circuit board (PCB) for a semiconductor package. This technology is evaluated as an advanced technology prior to the wafer level package (WLP) process.

In the process of manufacturing a semiconductor package, the coating process of coating liquids such as photoresist liquid is performed to the surface of a to-be-processed substrate. In prior arts, when the size of a substrate to be processed was small, a spin coating method was widely used in which the chemical liquid was applied to the surface of the substrate by rotating the substrate while supplying the chemical liquid to the center portion of the substrate.

However, as the size of the substrate to be processed increases, the spin coating method is rarely used. Slit coating method has been used in which a slit nozzle has a length corresponding to the width of the substrate, moves relative to the substrate, and supplies the chemical liquids on the substrate.

More specifically, the manufacturing a semiconductor package is performed sequentially by supplying a chemical liquid to the surface of the substrate, drying the chemical liquids on the substrate, and exposing the chemical liquid to be a required pattern on the substrate.

On the other hand, if the substrate is bent or warped before the chemical liquid supplied on the substrate is dried, the chemical liquid is caused to flow down and thus the coating thickness of the chemical liquid becomes inconstant. Therefore, it is necessary to maintain the substrate to be horizontally flat during the coating process.

However, in prior arts, as the substrate was transferred to the drying unit by a transfer unit right after the chemical liquid was supplied on its surface of the substrate, there has been a problem that the substrate was bent or warped as the substrate was lifted by lift pins before the chemical liquid was not yet cured, whereby coated liquid flew down on the surface of the substrate and the thickness of the chemical coating film became ununiform.

In particular, as the edge portion of the substrate was not supported by the lifting pins in the lifting process, the edge portion of the substrate was deflected, whereby the chemical liquid flew down to the edge portion of the substrate resulting in uneven thickness of the coating film as well as in the coating film with stains.

Accordingly, in recent years, various studies have been made to prevent the chemical liquid supplied on the substrate from flowing down, and to uniformly form the thickness of the chemical liquid coating film.

### DETAILED DESCRIPTION OF THE INVENTION

### Objects of the Invention

The present invention has been made in view of the technical background described above and it is an object of the present invention is to provide a substrate processing apparatus capable of forming a chemical liquid coating film having a uniform thickness.

In particular, an object of the present invention is to enable the chemical liquid to be prevented from flowing down during the process of transferring the substrate coated with the chemical liquid to the drying unit.

In addition, an object of the present invention is to prevent the occurrence of stains and to improve the quality of the chemical coating film.

Moreover, an object of this invention is to shorten the processing time of a substrate and to improve a yield and process efficiency.

Moreover, an object of this invention is to maintain the horizontal flatness of a substrate uniformly during the substrate processing process, and to form the thickness of a chemical liquid coating film uniformly.

### SUMMARY OF THE INVENTION

According to a preferred embodiment of the present invention for achieving the above-described objects of the present invention, before transferring the substrate coated by the chemical liquid to the subsequent process unit, the chemical liquid is preliminarily dried. Therefore, even if the substrate is deflected during transferring the substrate, it is possible to prevent the chemical liquid coated on the substrate from flowing down, and thus to uniformly form the thickness of the chemical liquid coating film.

### The Advantageous Effects of the Invention

As described above, according to the present invention, an advantageous effect of forming a chemical coating film having a uniform thickness can be obtained.

In particular, according to the present invention, even if the substrate is warped or deflected at any part e.g., edge part of the substrate during the transfer process of the substrate on which the chemical liquid is coated, it is possible to obtain an advantageous effect that the thickness of the chemical liquid coating film is formed as uniform as the chemical liquid applied on the substrate is prevented from flowing down.

Further, according to the present invention, it is possible to obtain an advantageous effect of preventing the occurrence of stains and improving the quality of the chemical coating film.

In addition, according to the present invention, advantageous effects of shortening the processing time of the substrate and improving the yield and the process efficiency can be obtained.

Further, according to the present invention, the horizontal flatness of the substrate can be maintained uniformly during the processing of the substrate, and the advantageous effect of uniformly forming the thickness of the chemical coating layer can be obtained.

### Embodiments

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a view for explaining a substrate processing apparatus according to the present invention.

FIG. 2 is a view showing the preliminary drying unit of FIG. 1.

FIG. 3 is a diagram for explaining a chemical liquid coating unit as a substrate processing apparatus according to the present invention.

FIGS. 4 and 5 are views for explaining a preliminary drying unit as a substrate processing apparatus according to the present invention.

FIGS. 6 and 7 illustrate a substrate processing apparatus according to the present invention for explaining a substrate transfer process.

FIG. 8 is a substrate processing apparatus according to the present invention, which is a view for explaining a subsequent drying unit.

FIG. 9 is a substrate processing apparatus according to the present invention for explaining another embodiment of the substrate support.

FIGS. 10 to 13 are substrate processing apparatus according to the present invention, a view for explaining another embodiment of the substrate support.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

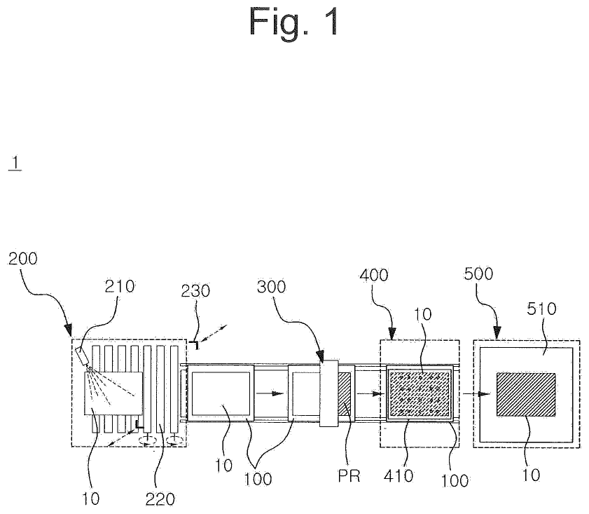

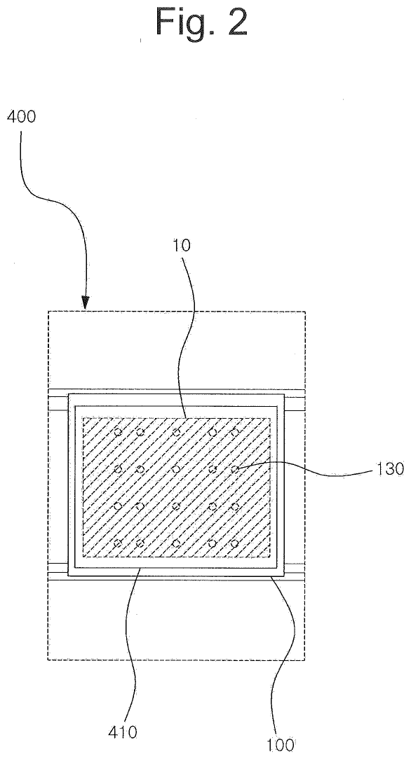

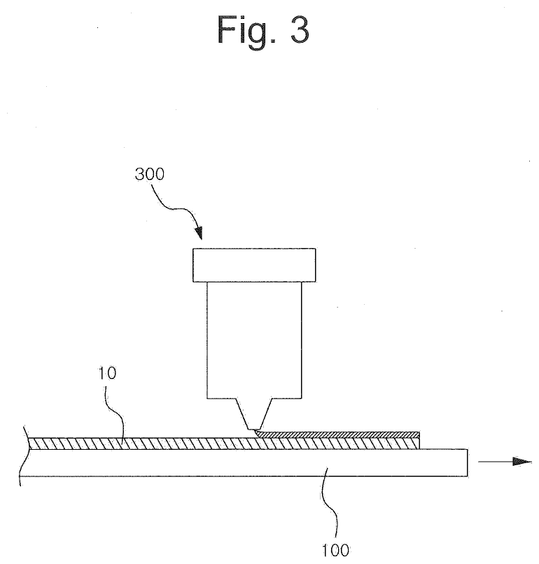

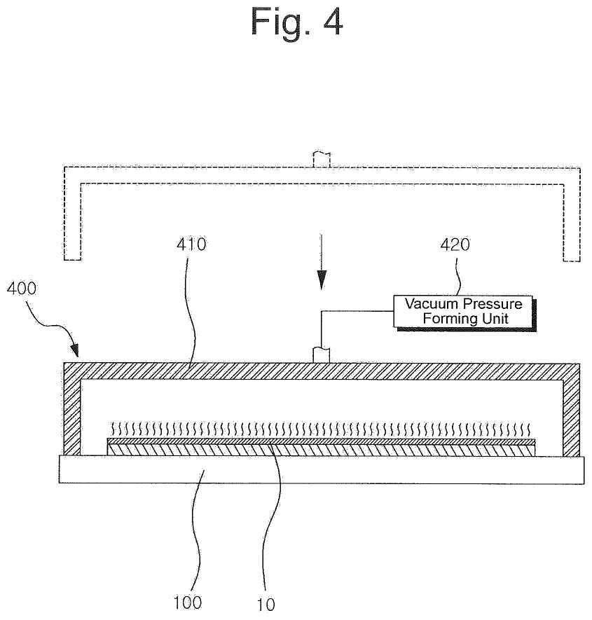

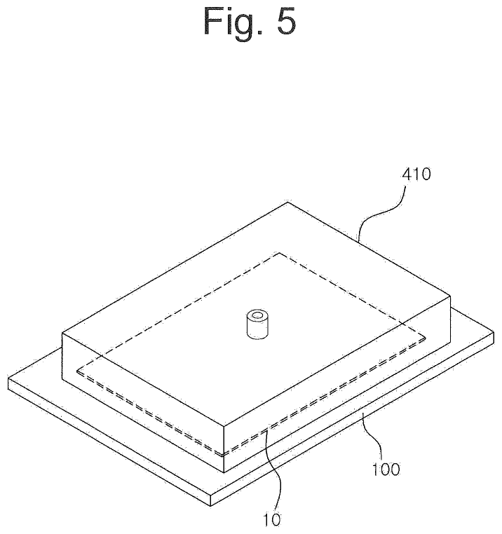

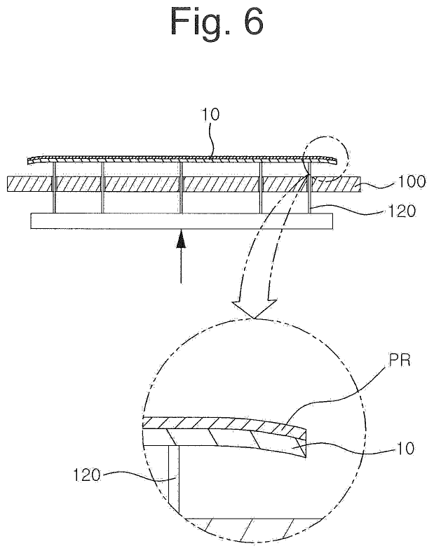

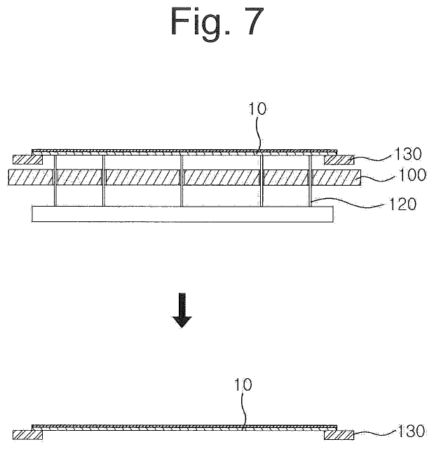

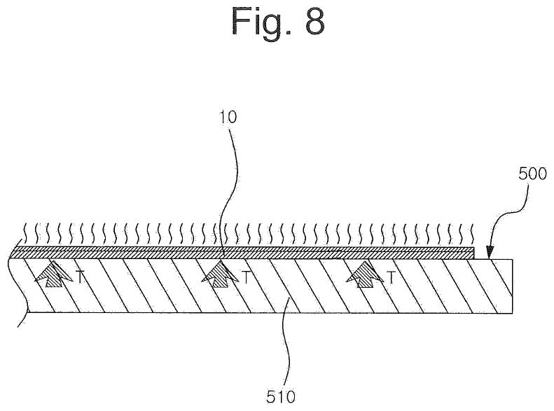

FIG. 1 is a view for explaining a substrate processing apparatus according to the present invention, FIG. 2 is a view showing the preliminary drying unit of FIG. 1, FIG. 3 is a diagram for explaining a chemical liquid coating unit as a substrate processing apparatus according to the present invention, and FIGS. 4 and 5 are views for explaining a preliminary drying unit as a substrate processing apparatus according to the present invention. FIGS. 6 and 7 illustrate a substrate processing apparatus according to the present invention for explaining a substrate transfer process, FIG. 8 is a substrate processing apparatus according to the present invention, which is a view for explaining a subsequent drying unit.

As shown in FIGS. 1 to 8, a substrate processing apparatus 1 for coating chemical liquid on a substrate according to an embodiment of the present invention, comprises: a substrate support 100 for supporting a substrate, a chemical liquid coating unit 300 for applying a chemical liquid on a substrate, and a preliminary drying unit for preliminarily drying the chemical liquid on the substrate in a state where the substrate is supported by the substrate support 100.

Before the substrate mounted on the substrate support 100 is transferred to a subsequent unit (for example, a main drying unit) in which a subsequent process is performed, the preliminary drying unit 400 preliminarily dries the chemical liquid on the substrate 10 in the state that the substrate is supported by the support 100.

This is to prevent the chemical liquid applied to the substrate from flowing down during the transfer process of the substrate and to form a chemical liquid coating film having a uniform thickness.

That is, immediately after the chemical is applied to the upper surface and coated on the substrate, the substrate is lifted using the lift pins, and thus the substrate is warped or deflected at a specific portion e.g., an edge portion of the substrate not supported by the lifting pins, which causes difference in the thickness of the chemical coating film due to the flow of the liquid on the substrate.

However, the present invention is configured that the chemical liquid is preliminarily dried immediately after the chemical liquid is applied to the substrate supported by the substrate support 100, before the substrate is transferred to a subsequent unit (e.g., main drying unit). Therefore, even if the bending deformation of the substrate is locally generated during the transfer process of the substrate, as the chemical liquid on the substrate is a little bit solidified so as not to not to flow down, the thickness of the chemical liquid coating film can be uniformly formed.

Furthermore, as the present invention performs the preliminary drying process directly at the substrate support where the chemical liquid is coated on the substrate, it is possible to obtain the advantageous effect of improving the yield and the process efficiency without increasing the additional processing time.

For reference, the substrate 10 may be supplied to the chemical liquid coating unit 300 after the cleaning process is completed in the cleaning processing unit 200.

Referring to FIG. 1, the cleaning processing unit 200 may be provided in various structures capable of performing a cleaning process on the substrate 10. The present invention is not limited or limited by the structure and the cleaning method of the cleaning processing unit 200.

For example, referring to FIG. 1, when the substrate 10 used in the panel level package is supplied, the cleaning liquid is injected at a high pressure from the cleaning liquid nozzle 210 to clean the surface of the substrate 10. The substrate 10 is transferred after the cleaning process to the chemical liquid coating unit 300 by the rotation of the transfer roller 220.

In addition, before the substrate 10 cleaned in the cleaning processing unit 200 is transferred to the chemical liquid coating unit 300, the posture and the position of the substrate 10 may be set aligned by the alignment member 230 having an approximately “L” shape to a predetermined posture and the position. In some cases, the substrate may be supplied to the chemical liquid coating unit without cleaning in the cleaning processing unit.

Referring to FIG. 3, the chemical liquid coating unit 300 is provided to apply a chemical liquid e.g., photoresist liquid PR on the surface of the substrate 10 on which the cleaning process is completed in the cleaning processing unit 200.

The chemical liquid may be coated by the chemical liquid coating unit 300 on the entire surface of the substrate 10 or on a portion divided into a plurality of cell regions.

For example, the chemical liquid coating unit 300 is installed to the gantry which is supported at both sides of the transfer path of the substrate 10. The chemical liquid coating unit 300 is provided to apply and coat the chemical liquid on the surface of the substrate 10. In addition, a slit nozzle having a length corresponding to the width of the substrate 10 is formed at the bottom end of the chemical liquid coating unit 300, and the chemical liquid may be discharged through the slit nozzle and applied to the surface of the substrate 10.

In addition, the chemical liquid coating unit 300 may be provided with a pre-discharge device (not shown). Here, before the chemical liquid is applied and coated on the substrate 10 through the slit nozzle, the pre-discharge device allows the slit nozzle to discharge the chemical liquid slightly so as to drop off the coating liquid remaining at the slit nozzle discharge port, and also to form the chemical liquid bead layer in advance.

The substrate support 100 is provided to horizontally and flatly support the substrate 10 during the chemical liquid coating process.

The substrate support 100 may be formed in various shapes and structures in which the substrate 10 may be supported. The present invention is not limited or limited by the shape and structure of the substrate support 100. For example, the substrate support 100 may be formed in a substantially square plate shape.

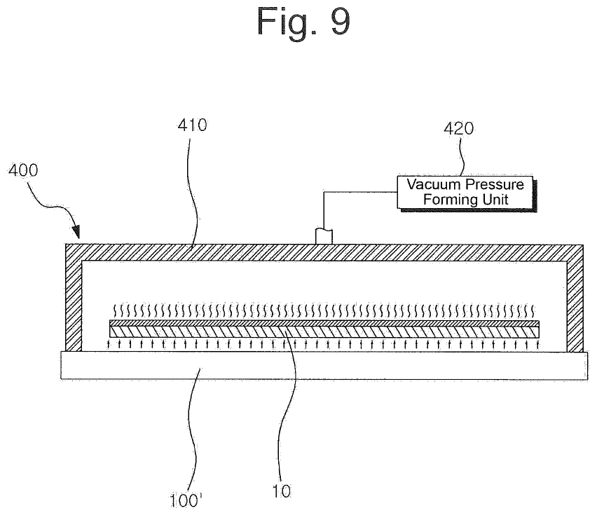

Here, the meaning that the substrate 10 is supported by the substrate support 100 is defined as that the bottom surface of the substrate 10 is flatly supported by the substrate support 100. For example, the substrate 10 is supported to on the upper surface of the substrate support 100. In some cases, the substrate may be configured to be fixed on the substrate support by suctioning the substrate from the substrate support. Alternatively, it is also possible to configure the substrate to be supported in a state of being floated at a uniform height from the substrate support (see FIG. 9).

In addition, the substrate support 100 may be provided to be movable with respect to the chemical coating unit 300. The chemical liquid coating on the substrate may be performed while the substrate support 100 moves with respect to the fixed chemical liquid coating unit 300.

For example, the substrate support 100 may be configured to linearly move along a transfer rail (not shown). According to other embodiment of the present invention, permanent magnets of the N pole and the S pole are alternately arranged on the transfer rail. The substrate support 100 may be precisely positioned by the driving principle of the linear motor.

As shown in FIGS. 4 and 5, the preliminary drying unit 400 is provided to preliminarily dry the chemical liquid in a state that the substrate 10 on which the chemical liquid is applied is supported by the substrate support 100.

That is, before the substrate is transferred to the subsequent unit e.g., main dry unit, the preliminary drying unit 400 is configured to immediately a little bit dry the chemical liquid in the state that the substrate is supported by the substrate support 100 so that the chemical liquid may not flow any more on the substrate.

Here, the preliminary drying is defined as the chemical liquid being dried to a state in which the chemical liquid is prevented from flowing down on the substrate 10. In other words, the chemical liquid applied on the substrate 10 by the preliminary drying process in the preliminary drying unit 400 is dried to such an extent that the chemical liquid does not flow even if the substrate 10 is warped or deflected during the transfer of the substrate.

More specifically, the preliminary drying unit 400 is configured to partially dry some of the solvent contained in the chemical liquid. Of course, it is also possible to dry all the solvent contained in the chemical liquid by the preliminary drying process by the preliminary drying unit 400, however, as the preliminary drying process takes very long time to dry all the solvent therein, it is preferable for the preliminary drying unit 400 to dry imperfectly the solvent contained in the chemical liquid to the extent that the chemical liquid does not flow down.

The preliminary drying unit 400 may be formed in various structures capable of performing a preliminary drying process for the chemical liquid.

Preferably, the preliminary drying unit 400 is configured to dry the chemical liquid in a vacuum state. During the preliminary drying process, the temperature of the substrate support 100 is kept uniform and constant. More preferably, the preliminary drying unit 400 is configured to dry the chemical liquid in a vacuum range of −50 kpa to −90 kpa.

In this way, the preliminary drying unit 400 can maintain the temperature of the substrate support 100 uniformly without heating and can dry the chemical liquid in a vacuum state, so that the substrate support during the chemical liquid coating process for the next substrate can be maintained as the same temperature thereby preventing the occurrence of spots or stains due to the temperature variation of substrate support 100.

That is, in case that the substrate support 100 is heated, as the temperature of the substrate support 100 may vary, the coating quality by chemical liquid coating process for a next substrate coating quality is deteriorated and staining occurs due to temperature variation for each region of the substrate support 100. On the other hand, in the present invention, as the temperature of the substrate support 100 is uniformly maintained during the preliminary drying process, the temperature change of the substrate support 100 does not happen, and thus stains or spots due to the temperature variations do not generated on the substrate after the coating process thereby improving coating quality.

For example, the preliminary drying unit 400 includes a drying chamber member 410 disposed to cover and accommodate the substrate 10 in its inner space, and a vacuum pressure forming unit 420 for applying a vacuum pressure to the inner space of the drying chamber member 410.

More specifically, the drying chamber member 410 is formed in a box shape of which the lower part is open and is movable in the vertical direction. When a substrate 10 is disposed at a preliminary drying position where a preliminary drying process is performed, the drying chamber member 410 moves downward and covers and accommodates the substrate.

Here, the preliminary drying position is defined as a position where the substrate 10 has completely passed through the chemical coating unit 300 so that the chemical liquid is discharged and fully coated on the predetermined region of the substrate. The preliminary drying position allows the vertical movement of the drying chamber member 410.

At this time, the internal space of the drying chamber member 410 in which the preliminary drying process is performed may be configured to be completely sealed from the outside. However, the present invention is not limited thereto, and the internal space of the drying chamber member 410 may not be completely sealed within the scope in which the preliminary drying process may be performed.

The vacuum pressure forming unit 420 may be configured to apply a vacuum pressure to the inner space of the drying chamber member 300 in various ways according to the required conditions and design specifications. The scope of the present invention is not limited or limited by the type and structure of the vacuum pressure forming unit 420.

As shown in FIGS. 6 and 7, the substrate processing apparatus 1 comprises a lifting unit 120 for lifting the substrate 10 at the substrate support 100, and a transfer unit 130 for transferring the substrate 10 lifted by the lifting unit 120 to the subsequent drying unit 500. Herein, the preliminary drying unit 400 preliminarily dries the substrate before the substrate is lifted by the lifting unit 120 in the substrate support 100.

As an example, the subsequent drying unit 500 is configured to dry the chemical liquid in a higher temperature range than the preliminary drying unit 400. In some cases, it is also possible to configure the subsequent drying unit to heat dry the chemical liquid of the substrate in a vacuum state.

The lifting unit 120 includes a plurality of lifting pins (not shown) provided to be movable in the vertical direction. The bottom of the substrate may be lifted apart from the top surface of the substrate support 100 by the lifting unit 120.

The transfer unit 130 may be formed in various structures capable of transferring the substrate 10 lifted by the lifting unit 120. For example, the transfer unit 130 may be configured to transfer the substrate with partially supporting the edge bottom surface of the substrate 10 lifted by the lifting unit 120.

Referring to FIG. 8, the substrate processing apparatus comprises a subsequent drying unit 500 that receives the substrate 10 experienced the preliminary drying process by the preliminary drying unit 400 and subsequently dries the chemical liquid.

Subsequent drying unit 500 may be formed in a variety of structures that can dry the chemical liquid in a thermal drying method. As an example, the subsequent drying unit 500 includes a heating plate for heating the substrate. The heating plate may be formed in the form of a square plate, and the substrate 10 on which the preliminary drying process was performed is seated on the upper surface of the heating plate by the transfer unit 130.

For reference, as the heating plate, one heating plate having a size larger than the substrate 10 may be used. In some cases, it is also possible to continuously arrange a plurality of heating plates having a size smaller than the substrate.

In addition, the heating temperature of the heating plate may be uniformly maintained at a predetermined temperature during the heat drying process for the substrate 10.

Alternatively, it is also possible to configure that the heating temperature of the substrate to change gradually (e.g., to increase gradually) during the heat drying process on the substrate. In this manner, by gradually increasing the heating temperature of the substrate during the heat drying process on the substrate, the solvent component contained in the chemical liquid applied on the substrate 10 can be dried with gradually evaporating the solvent from the chemical liquid. Accordingly, it is possible to solve the problem that the solvent component contained in the chemical liquid is suddenly dried to remain stains and spots due to the flow of the chemical liquid during the drying process.

For reference, the substrate may be heated for a predetermined time at a predetermined heating temperature in a stationary state in the subsequent drying unit 500. In some cases, it is also possible for the substrate to be heated while moving slowly without stopping while passing through the subsequent drying unit.

In addition, the heating plates of the subsequent drying units 500 may be disposed below the substrate 10, but in some cases, the heating plates of the subsequent drying units may be disposed above the substrate.

On the other hand, in the above-described and illustrated embodiment of the present invention, it has been described that the substrate is supported in contact with the upper surface of the substrate support 100. However, in some cases the substrate support may be configured to float and transfer the substrate.

Hereinafter, another embodiment of the substrate support 100′ will be described with reference to FIG. 9.

FIG. 9 is a substrate processing apparatus according to the present invention for explaining another embodiment of the substrate support. In addition, the same or equivalent reference numerals are given to the same or equivalent components as those described above, and detailed description thereof will be omitted.

Referring to FIG. 9, according to another embodiment of the present invention, the substrate support 100′ is configured to transfer the substrate in a floating state.

Here, the floating of the substrate 10 means a state in which the substrate 10 is floated in the air at a predetermined interval.

Preferably, referring to FIG. 9, the substrate support 100′ includes an ultrasonic wave generator (e.g., a vibration plate excited by ultrasonic waves, not shown) disposed under the substrate 10. The substrate 10 is floated by the vibration energy generated in the ultrasonic generator. At this time, the substrate 10, which is floated by the substrate support 100′, may be transferred as the transfer member moves while one side is gripped by a transfer member (not shown).

In this way, by floating the substrate 10 by the vibration energy by the ultrasonic generator, it is possible to precisely control the floating force of the substrate 10, and damage and deformation caused by external contact may be minimized while the substrate 10 is transported.

In particular, in the floating method using the ultrasonic wave generation unit, as the floating force can be formed uniform over the entire substrate 10, in the coating region where the chemical liquid is applied and coated from the chemical liquid applying unit to the substrate the substrate 10, the height of the substrate with respect to the chemical liquid coating unit 300 can be more precisely controlled and maintained.

The preliminary drying unit 400 is arranged to cover the substrate 10 in a state where the substrate is floatingly supported, and the substrate 10 is preliminarily dried in the preliminary drying unit 400 immediately before being transferred to the subsequent drying unit 500. (See 500 in FIG. 1)

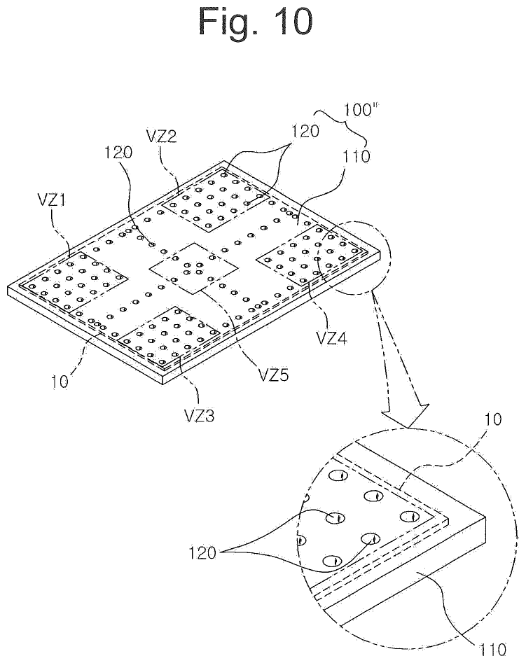

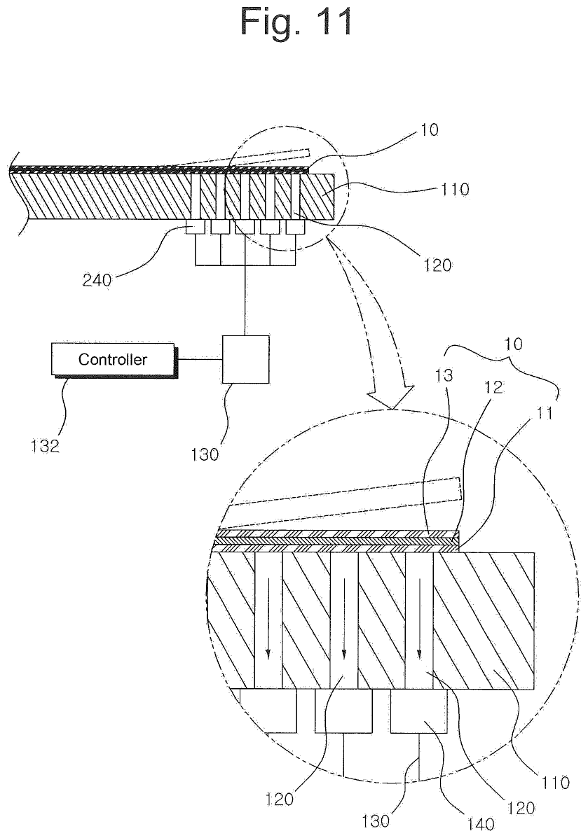

FIGS. 10 to 13 illustrate a substrate processing apparatus according to another exemplary embodiment of the present invention. In addition, the same or equivalent reference numerals are given to the same or equivalent components as those described above, and detailed description thereof will be omitted.

As shown in FIGS. 10 to 13, according to another embodiment of the present invention, the substrate support 100″ supports the substrate 10 evenly while the substrate 10 is processed along a predetermined coating process path.

Here, the meaning that the substrate support 100″ supports the substrate 10 evenly while the substrate 10 is processed along a predetermined coating process path is defined as that the substrate support 100″ is maintained as evenly flat while the substrate support 100″ may be stationary or moving along the predetermined coating process path.

More specifically, the substrate support 100″ sucks and fixes the substrate 10 onto its upper surface and supports the substrate 10 evenly and flatly.

For this, the substrate support 100″ may include a carrier main body 110 on which the substrate 10 is seated, and a plurality of suction holes 120 formed in the carrier main body 110 to suck and fix the substrate 10 to the carrier main body 110. In other words, the substrate support 100″ may be formed in the form of a porous plate with the plurality of suction holes 120, and the substrate 10 is sucked and fixed to the main body 110 by the vacuum pressure applied to the suction holes 120.

In this case, the plurality of suction holes 120 may form a plurality of suction zones VZ1 to VZ5 that are independently divided. For example, the edge suction zones VZ1 to VZ4 and the center suction zone VZ5 may be formed in the carrier body 110. The number and shape (e.g., round, triangular, crossover, etc.) of the suction zones may vary in accordance with the required conditions and design specifications.

In addition, the substrate processing apparatus 1 may further comprises a controller 132 that simultaneously or sequentially controls the suction of the plurality of suction zones to the substrate 10. For example, the controller 132 may allow the edge of the substrate 10 to be firstly sucked in the edge region of the carrier body 110, and then allow the center portion of the substrate 10 to be sucked later in the central region of the carrier body 110. In some cases, the substrate may be gradually sucked in one direction from one side toward the other side of the substrate, or the bottom surface of the substrate may be simultaneously sucked as a whole.

The carrier body 110 is connected to the vacuum unit 130 for applying a vacuum pressure to the suction holes 120, the substrate 10 is sucked to the a carrier body by the vacuum pressure applied to the suction holes 120 from the vacuum unit 130.

Preferably, the vacuum unit 130 is selectively detachably coupled to the substrate support 100″, and vacuum unit 130 is detached from the substrate support 100″ during the movement (e.g., from the chemical coating unit to the subsequent drying unit) of the substrate support 100″. Unit 130 is separated from substrate support 100 ”.

More preferably, the substrate support 100” includes a vacuum holding part 140 which maintains a vacuum state of the suction holes 120 in a state where the vacuum unit 130 is separated from the substrate support 100″.

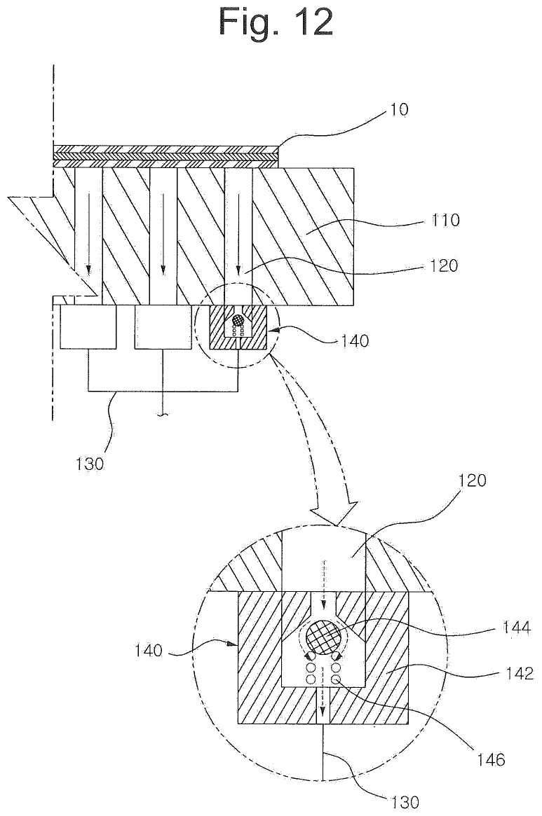

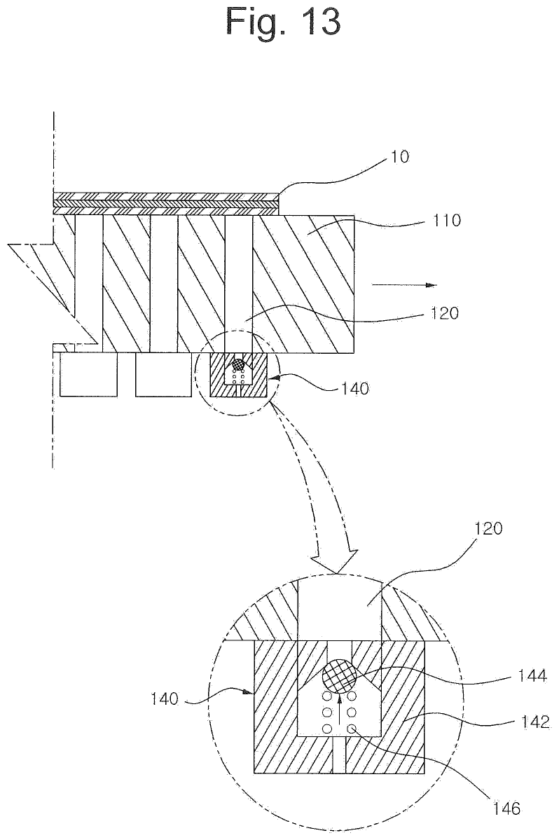

For example, referring to FIGS. 12 and 13, the vacuum holding part 140 includes a coupler body 142 mounted in communication with the suction holes 120 and detachably coupled with the vacuum unit 130, valve member 144 accommodated to be linearly movable inside the coupler body 142 and selectively opening or closing the inlet of the suction holes 120, and an elastic member 146 for elastically supporting the linear movement of the valve member 144 in the coupler body 142. Herein, when the vacuum unit 130 is separated from the coupler body 142, the valve member 144 elastically blocks and closes the inlet of the suction holes 120.

The valve member 144 may be formed in various forms that can open and close the inlet of the suction holes 120. For example, the valve member 144 may be formed in a ball shape. The elastic member 146 may be formed in various forms that can elastically support the liner movement of the valve member 144. For example, a conventional spring may be used as the elastic member 146.

In some cases, when the vacuum holding part is separated from the substrate support, diverse forms of quick couplers capable of maintaining the vacuum state of the suction holes may be used. The type and structure of the coupler can be changed in various ways according to the requirements and design specifications.

As such, the vacuum holding part 140 is provided in the substrate support 100″, and the vacuum state of the suction holes 120 are maintained even after the vacuum unit 130 is separated from the substrate support 100″, whereby the advantageous effect which stably prevent the substrate 10 from being warped can also be acquired during the movement of the substrate and the substrate support. In particular, when the substrate is warped while the substrate is being moved on which the substrate the chemical liquid is coated, the chemical liquid flows down from the warpage portion of the substrate, so that it is difficult to form chemical liquid coating layer with the uniform thickness. However, according to the present invention, as the substrate 10 is horizontally and flatly supported while the substrate coated with the chemical liquid moves, the chemical liquid coating layer is kept uniform in thickness and thus spots and stains are not generated.

For example, the substrate 10 used for the panel level package is formed by stacking a plurality of layers having different thermal conductivity. That is, the panel level package substrate 10 includes a first copper layer 11, an epoxy layer 12 (or glass fiber layer) stacked on top of the first copper layer 11, and a second copper layer 13 stacked on the top of the epoxy layer 12. For reference, in the panel level package, the first copper layer 11 and the second copper layer 13 of the substrate 10 may be used for wiring between chips. Herein, as the first copper layer 11 and the second copper layer is formed of different thermal conductivity from the epoxy layer 12, smile shaped warpage deformation that the edge portions of both sides of the substrate are deflected above compared with the central portion of the substrate may occur, or crying shaped warpage deformation that the edge portions of both sides of the substrate are deflected below compared with the central portion of the substrate may occur.

However, according to the present invention, as the substrate is horizontally and flatly supported by the substrate support 100″, the warpage of the substrate is forced to be suppressed and thus is maintained as horizontally flat during the coating process for the substrate 10.

In addition, the substrate 10 is sucked by the substrate support 100″ to be maintained as a horizontal flat state while the coating process on the substrate 10 is being processed, thereby uniformly forming the thickness of the chemical coating film without stains and spots. In addition, as the substrate 10 may be heated to a uniform temperature (in the preliminary drying process and in the subsequent drying process), it is possible to obtain an advantageous effect of improving the thickness uniformity and quality of the chemical coating film.

On the other hand, the warpage of the substrate may occur due to the difference in thermal conductivity between the layers forming the substrate, but may also occur while the chemical liquid coated on the substrate is dried. However, in the present invention, as the warpage of the substrate is forcibly suppressed (sucked by the substrate support) during the drying of the chemical liquid, it is possible to obtain an advantageous effect of preventing the thickness variation of the chemical coating layer due to the warpage of the substrate during the drying of the chemical liquid.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A substrate processing apparatus, comprising:
a substrate support for supporting the substrate;
a chemical liquid coating unit for coating chemical liquid on the substrate; and
a preliminary drying unit for preliminarily drying the chemical liquid on the substrate in a state that the substrate is supported by the substrate support.

2. The substrate processing apparatus of claim 1, wherein the preliminary drying unit preliminarily dries the chemical liquid in vacuum state.

3. The substrate processing apparatus of claim 2, wherein the preliminary drying unit includes:
a drying chamber member for accommodating the substrate,
a vacuum pressure forming unit for applying a vacuum pressure to the inner space of the drying chamber member.

4. The substrate processing apparatus of claim 3, wherein the chemical liquid coating unit is fixed, and the substrate moves with respect to the chemical liquid coating unit and the chemical liquid is coated on the substrate.

5. The substrate processing apparatus of claim 4, wherein the lower part of the drying chamber member is open and the drying chamber member is movable in the vertical direction, and wherein when a substrate 10 is disposed at a preliminary drying position where a preliminary drying process is performed, the drying chamber member 410 moves downward and accommodates the substrate in its inner space.

6. The substrate processing apparatus of claim 4, wherein the substrate support is movable with respect to the chemical liquid coating unit.

7. The substrate processing apparatus of claim 2, wherein the temperature of the substrate support is maintained constant while the preliminary drying unit preliminarily dries the chemical liquid on the substrate.

8. The substrate processing apparatus of claim 2, wherein the preliminary drying unit preliminarily dries the chemical liquid on the substrate under the pressure of between −50 kpa and −90 kpa.

9. The substrate processing apparatus of claim 1, further comprising:
a subsequent drying unit for subsequently drying the chemical liquid on the substrate to which a preliminary drying process is already performed.

10. The substrate processing apparatus of claim 9, wherein the subsequent drying unit dries the chemical liquid on the substrate in higher temperature than the temperature in the preliminary drying unit.

11. The substrate processing apparatus of claim 9, further comprising:
a lifting unit for lifting the substrate at the substrate support; and
a transfer unit for transferring the substrate lifted by the lifting unit to the subsequent drying unit.

12. The substrate processing apparatus of claim 1, wherein the preliminary drying unit dries the chemical liquid to the state in which the chemical liquid is prevented from flowing down on the substrate.

13. The substrate processing apparatus of claim 12, wherein the preliminary drying unit partially dries the solvent contained in the chemical liquid.

14. The substrate processing apparatus of claim 4, wherein the substrate support transfers the substrate in a state of being floated.

15. The substrate processing apparatus of claim 14, wherein the substrate support floats the substrate by the vibration energy generated in the ultrasonic generator.

16. The substrate processing apparatus of claim 1, wherein the substrate support includes a carrier body on which the substrate is seated, and a plurality of suction holes formed in the carrier main body to suck and fix the substrate; and
wherein the substrate is horizontally and flatly supported by the substrate support.

17. The substrate processing apparatus of claim 16, wherein the plurality of suction holes form a plurality of suction zones; and further comprising a controller for simultaneously or sequentially controlling the suction of the plurality of suction zones to the substrate.

18. The substrate processing apparatus of claim 16, wherein a vacuum unit is selectively detachably coupled to the substrate support, and wherein the vacuum unit is detached from the substrate support during the movement of the substrate support.

19. The substrate processing apparatus of claim 18, further comprising:
a vacuum holding part for maintaining a vacuum state of the suction holes in a state where the vacuum unit is separated from the substrate support.

20. The substrate processing apparatus of claim 19, wherein the suction holding unit includes
a coupler body mounted in communication with the suction holes and detachably coupled with the vacuum unit;
a valve member accommodated to be linearly movable inside the coupler body and selectively opening or closing the inlet of the suction holes; and
an elastic member for elastically supporting the linear movement of the valve member in the coupler body;
and wherein the valve member elastically blocks and closes the inlet of the suction holes when the vacuum unit is separated from the coupler body.
